(19) United States
(12) Patent Application Publication
(10) Pub. No.: US 2024/0349483 A1
(43) Pub. Date: Oct. 17, 2024

(54) SEMICONDUCTOR DEVICE

(71) Applicant: SAMSUNG ELECTRONICS CO., LTD., Suwon-si, (KR)

(72) Inventors: SOHYUN PARK, Suwon-si (KR); Inwoo KIM, Suwon-si (KR); Sangho LEE, Suwon-si (KR); Jihun LEE, Suwon-si (KR)

(21) Appl. No.: 18/415,754

(22) Filed: Jan. 18, 2024

(30) Foreign Application Priority Data
Apr. 12, 2023 (KR) 10-2023-0047969

(51) Int. Cl. H10B 12/00

(52) U.S. Cl. CPC H10B 12/315; H10B 12/0335; H10B 12/482

(57) ABSTRACT

A semiconductor device includes an active pattern on a substrate; a bit line structure on a central portion of the active pattern; a first spacer structure and a second spacer structure disposed on a first sidewall and a second sidewall, respectively, of the bit line structure, the first sidewall and the second sidewall of the bit line structure facing each other in the first direction; a lower contact plug on each of opposite end portions of the active pattern; and an upper contact plug on the lower contact plug. The upper contact plug may include a conductive pattern; and a conductive spacer covering a lower surface of the conductive pattern, wherein the conductive spacer contacts an outer sidewall of the first spacer structure, and does not contact an outer sidewall of the second spacer structure.

### CROSS-REFERENCE TO RELATED APPLICATION

This application claims priority under 35 U.S.C. § 119 to Korean Patent Application No. 10-2023-0047969, filed on Apr. 12, 2023, in the Korean Intellectual Property Office, the disclosure of which is hereby incorporated by reference in its entirety.

### BACKGROUND

### 1. Field

Example embodiments relate to a semiconductor device.

### 2. Description of Related Art

A dynamic random access memory (DRAM) device may include a bit line structure having a conductive structure and an insulation structure which are sequentially stacked, a capacitor, and an upper contact plug on which the capacitor is disposed. The upper contact plug may be formed by forming a metal layer on the bit line structure and patterning the metal layer. The height of the insulation structure included in the bit line structure may be increased so as to prevent the conductive structure included in the bit line structure from being damaged during the patterning of the metal layer of the upper contact plug.

### SUMMARY

According to example embodiments, there is provided a semiconductor device. The semiconductor device may include an active pattern on a substrate; a gate structure extending through an upper portion of the active pattern in a first direction substantially parallel to an upper surface of the substrate; a bit line structure on a central portion of the active pattern, the bit line structure extending in a second direction substantially parallel to the upper surface of the substrate and substantially perpendicular to the first direction; a first spacer structure and a second spacer structure disposed on a first sidewall and a second sidewall, respectively, of the bit line structure, the first sidewall and the second sidewall of the bit line structure facing each other in the first direction; a lower contact plug on each of opposite end portions of the active pattern; and an upper contact plug on the lower contact plug. The upper contact plug may include a conductive pattern; and a conductive spacer covering a lower surface of the conductive pattern, wherein the conductive spacer contacts an outer sidewall of the first spacer structure, and does not contact an outer sidewall of the second spacer structure.

According to example embodiments, there is provided a semiconductor device. The semiconductor device may include an active pattern on a substrate; a gate structure extending through an upper portion of the active pattern in a first direction substantially parallel to an upper surface of the substrate; a bit line structure on a central portion of the active pattern, the bit line structure extending in a second direction substantially parallel to the upper surface of the substrate and substantially perpendicular to the first direction; a spacer structure on each of opposite sidewalls in the first direction of the bit line structure; a lower contact plug on each of opposite end portions of the active pattern; and an upper contact plug on the lower contact plug. The upper contact plug may include a conductive pattern; and a conductive spacer covering a lower surface of the conductive pattern, wherein the conductive spacer is disposed on the spacer structure and the lower contact plug, and a cross-section in the first direction of the conductive spacer has a shape of a staircase.

According to example embodiments, there is provided a semiconductor device. The semiconductor device may include active patterns on a substrate; an isolation pattern on a substrate, the isolation pattern covering sidewalls of the active patterns; gate structures each extending through upper portions of the active patterns and the isolation pattern in a first direction substantially parallel to an upper surface of the substrate, the gate structures being spaced apart from each other in a second direction substantially parallel to the upper surface of the substrate and substantially perpendicular to the first direction; bit line structures each extending in the second direction on central portions of ones of the active patterns disposed in the second direction, the bit line structures being spaced apart from each other in the first direction; a first spacer structure and a second spacer structure disposed on a first sidewall and a second sidewall, respectively, of each of the bit line structures, the first sidewall and the second sidewall facing each other in the first direction; lower contact plugs disposed on opposite end portions, respectively, of the active patterns; metal silicide patterns disposed on the lower contact plugs, respectively; protection patterns disposed on the metal silicide patterns, respectively, each of the protection patterns including a metal; an insulation pattern on the protection patterns, the insulation pattern covering sidewalls of the upper contact plugs; upper contact plugs disposed on the protection patterns, respectively, each of the upper contact plugs may include a conductive pattern and a conductive spacer covering a lower surface of the conductive pattern; and capacitors disposed on the upper contact plugs, respectively, wherein the insulation pattern contacts upper surfaces of the protection patterns.

### BRIEF DESCRIPTION OF THE DRAWINGS

Features will become apparent to those of skill in the art by describing in detail exemplary embodiments with reference to the attached drawings, in which:

FIG. 1 is a plan view illustrating a semiconductor device in accordance with example embodiments.

FIG. 2 is a cross-sectional view taken along line A-A′ of FIG. 1.

FIGS. 3 to 23 are plan views and cross-sectional views of stages in a method of manufacturing a semiconductor device according to example embodiments.

FIGS. 24 to 26 are a plan view and a cross-sectional view, respectively, illustrating a semiconductor device according to example embodiments.

### DETAILED DESCRIPTION

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a substrate 100, which may be substantially orthogonal to each other, may be referred to as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of the substrate 100 may be referred to as a vertical direction.

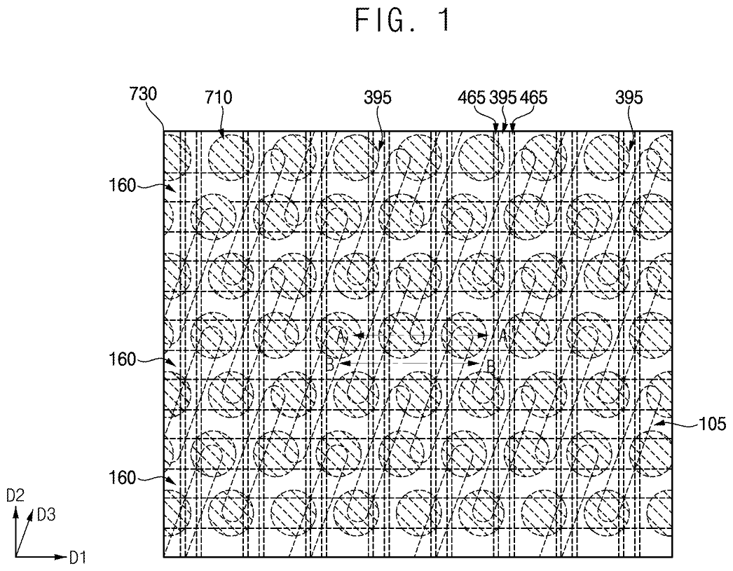

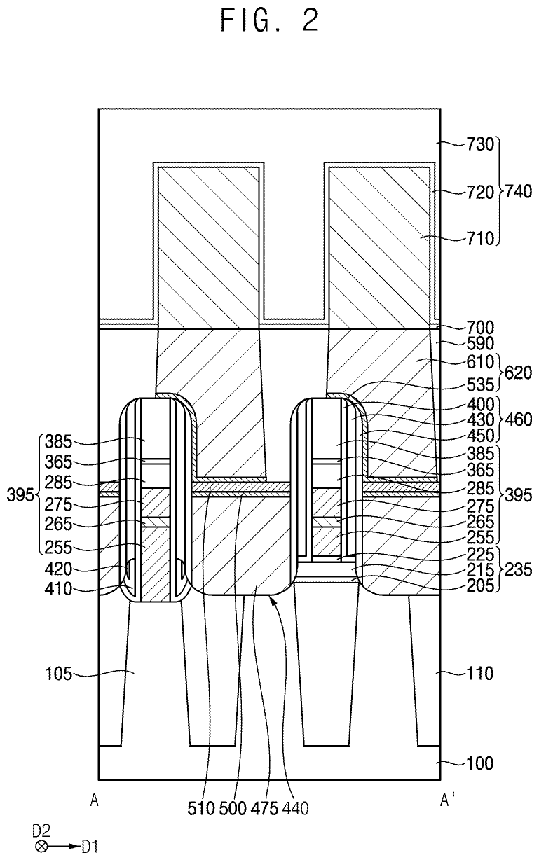

FIG. 1 is a plan view illustrating a semiconductor device in accordance with example embodiments, and FIG. 2 is a cross-sectional view along line A-A′ of FIG. 1.

Referring to FIGS. 1 and 2, the semiconductor device may include an active pattern 105, a gate structure 160, a bit line structure 395, a lower contact plug 475, a protection pattern 510, an upper contact plug 620 and a capacitor 740 on the substrate 100.

The semiconductor device may further include an isolation pattern 110, a spacer structure 460, a second capping pattern 485, an insulation pattern structure 235, fourth and fifth insulation patterns 410 and 420, a metal silicide pattern 500, a sixth insulation pattern 590 and a second etch stop pattern 700.

The active pattern 105 may extend in the third direction D3, and a plurality of active patterns 105 may be spaced apart from each other in the first and second directions D1 and D2. A sidewall of the active pattern 105 may be covered by the isolation pattern 110. The active pattern 105 may include substantially the same material as the substrate 100, and the isolation pattern 110 may include an oxide, e.g., silicon oxide.

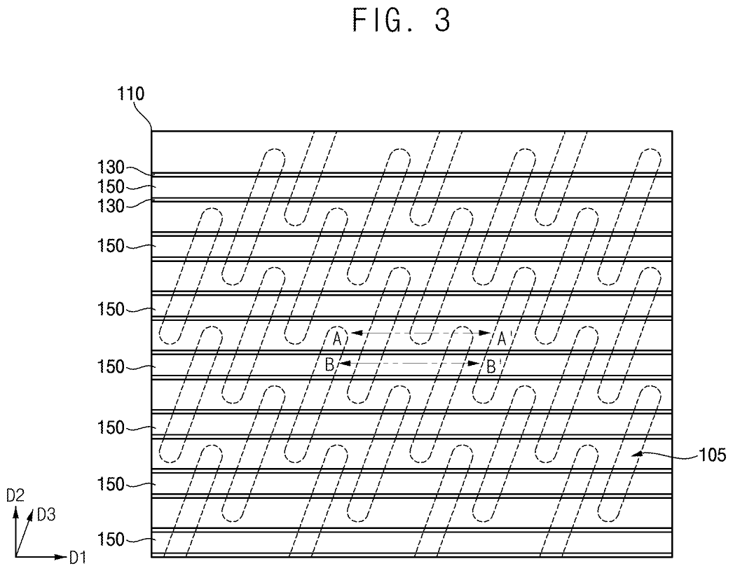

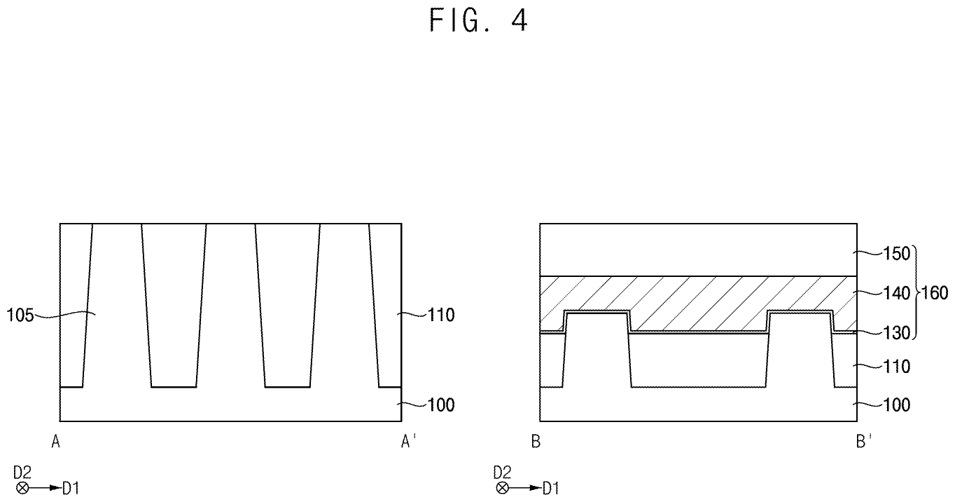

Referring to FIGS. 1 and 2 together with FIGS. 3 and 4, the gate structure 160 may be formed in a second recess extending in the first direction D1 through upper portions of the active patterns 105 and the isolation pattern 110. The gate structure 160 may include a gate insulation pattern 130 on a bottom and a sidewall of the second recess, a gate electrode 140 on a portion of the gate insulation pattern 130 on the bottom and a lower sidewall of the second recess, and a gate mask 150 on the gate electrode 140 and filling an upper portion of the second recess.

The gate insulation pattern 130 may include an oxide, e.g., silicon oxide, the gate electrode 140 may include, e.g., a metal, a metal nitride, a metal silicide, etc., and the gate mask 150 may include an insulating nitride, e.g., silicon nitride. In example embodiments, the gate structure 160 may extend in the first direction D1, and a plurality of gate structures 160 may be spaced apart from each other in the second direction D2.

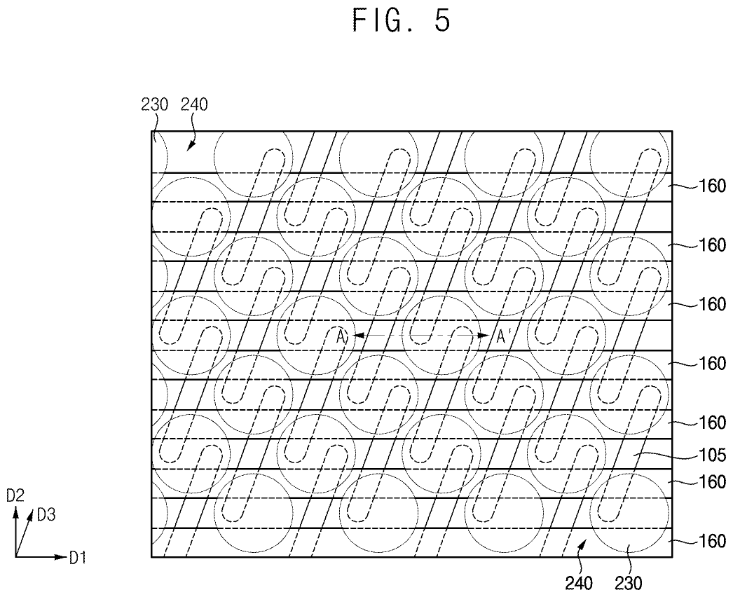

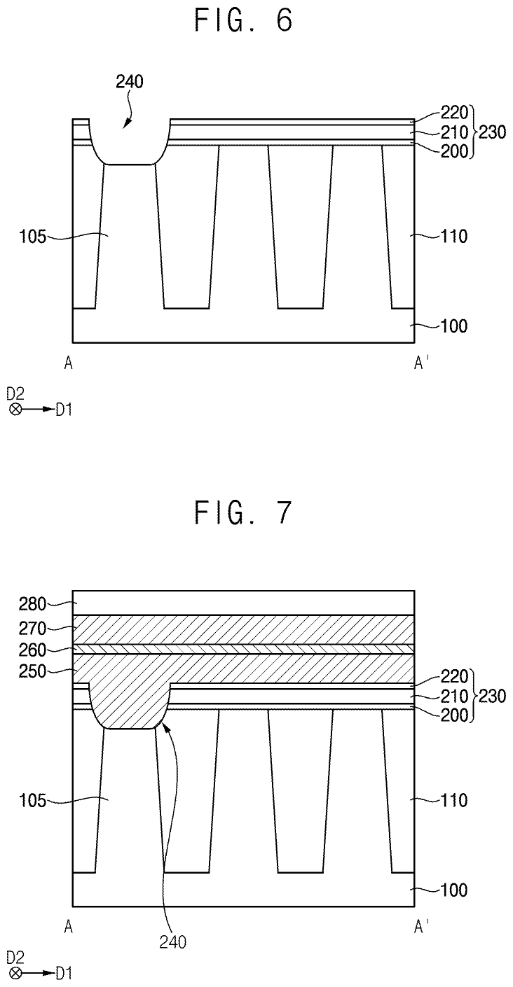

Referring to FIGS. 1 and 2 together with FIGS. 5 and 6, a first opening 240 extending through an insulating layer structure 230 and exposing upper surfaces of the active pattern 105, the isolation pattern 110, and the gate mask 150 of the gate structure 160 may be formed, and an upper surface of a central portion in the third direction D3 of the active pattern 105 may be exposed by the first opening 240.

In example embodiments, an area of a bottom of the first opening 240 may be greater than an area of the upper surface of the active pattern 105. Thus, the first opening 240 may also expose an upper surface of a portion of the isolation pattern 110 adjacent to the active pattern 105. Additionally, the first opening 240 may extend through upper portions of the active pattern 105 and the portion of the isolation pattern 110 adjacent thereto, and thus the bottom of the first opening 240 may be lower than an upper surface of each of opposite edge portions in the third direction D3 of the active pattern 105, e.g., relative to a bottom of the substrate 100.

Referring back to FIG. 2, the bit line structure 395 may include a first conductive pattern 255, a first barrier pattern 265, a second conductive pattern 275, a first mask 285, a first etch stop pattern 365, and a first capping pattern 385 sequentially stacked in the vertical direction on the first opening 240 or the insulation pattern structure 235. The first conductive pattern 255, the first barrier pattern 265, and the second conductive pattern 275 may collectively form a conductive structure, and the first mask 285, the first etch stop pattern 365, and the first capping pattern 385 may collectively form an insulation structure.

The first conductive pattern 255 may include, e.g., doped polysilicon, the first barrier pattern 265 may include a metal nitride, e.g., titanium nitride, or a metal silicon nitride, e.g., titanium silicon nitride, the second conductive pattern 275 may include a metal, e.g., tungsten, and each of the first mask 285, the first etch stop pattern 365, and the first capping pattern 385 may include an insulating nitride, e.g., silicon nitride. In example embodiments, the bit line structure 395 may extend (e.g., lengthwise) in the second direction D2 on the substrate 100, and a plurality of bit line structures 395 may be spaced apart from each other in the first direction D1.

The spacer structure 460 may include first to third spacers 400, 430 and 450 sequentially stacked on a sidewall in the first direction D1 of the bit line structure 395. In example embodiments, the spacer structures 460 may be disposed on opposite sidewalls, respectively, in the first direction D1 of the bit line structure 395, and may be symmetrical with respect to the bit line structure 395. Accordingly, the first to third spacers 400, 430 and 450 included in the respective spacer structures 460 may be symmetrical with respect to the bit line structure 395. Each of the first and the third spacers 400 and 450 may include an insulating nitride, e.g., silicon nitride, and the second spacer 430 may include an oxide, e.g., silicon oxide.

The insulation pattern structure 235 may be formed on the active pattern 105 and the isolation pattern 110 under the bit line structure 395, and may include first, second and third insulation patterns 205, 215 and 225 sequentially stacked in the vertical direction. The first and third insulation patterns 205 and 225 may include an oxide, e.g., silicon oxide, and the second insulation pattern 215 may include an insulating nitride, e.g., silicon nitride.

The fourth and fifth insulation patterns 410 and 420 may be formed in the first opening 240, and may contact a lower sidewall of the bit line structure 395. The fourth insulation pattern 410 may include an oxide, e.g., silicon oxide, and the fifth insulation pattern 420 may include an insulating nitride, e.g., silicon nitride.

The contact plug structure may include a lower contact plug 475, a metal silicide pattern 500, a protection pattern 510, and an upper contact plug 620 sequentially stacked in the vertical direction on the active pattern 105 and the isolation pattern 110.

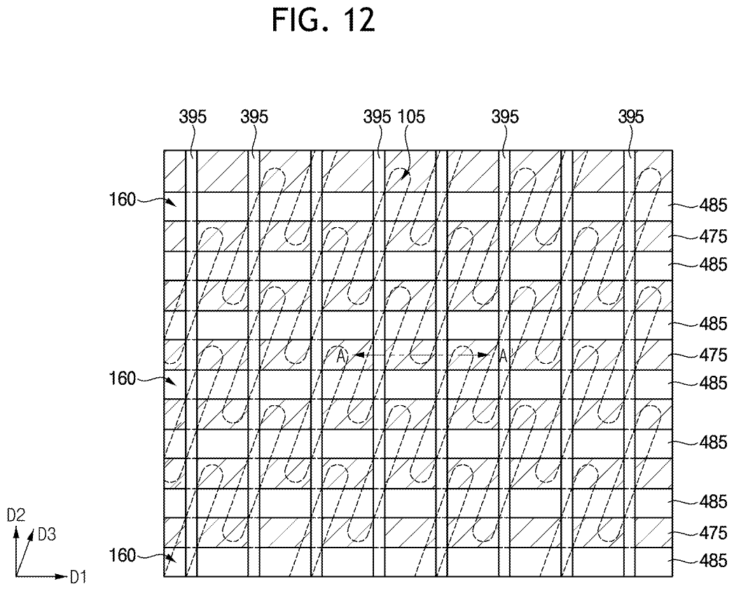

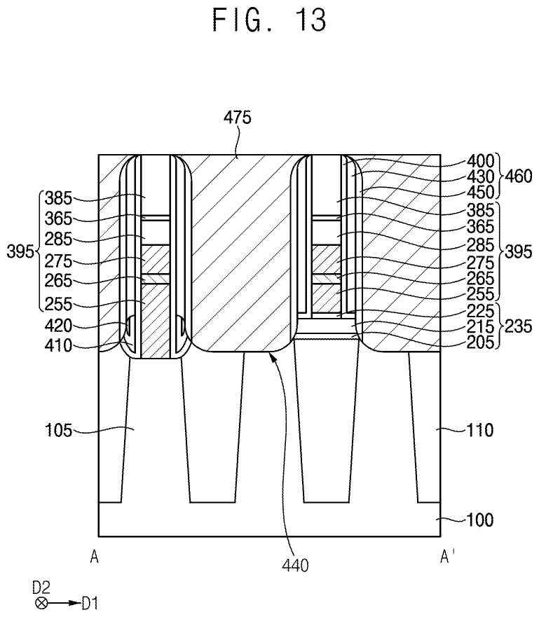

The lower contact plug 475 may contact (e.g., directly contact) the upper surface of each of opposite edge portions in the third direction D3 of the active pattern 105. In example embodiments, a plurality of lower contact plugs 475 may be spaced apart from each other in the second direction D2 between the bit line structures 395, and the second capping pattern 485 (FIG. 12) may be disposed between neighboring ones of the lower contact plugs 475 in the second direction D2. The lower contact plug 475 may include, e.g., doped polysilicon, and the second capping pattern 485 may include an insulating nitride, e.g., silicon nitride.

The metal silicide pattern 500 may include, e.g., titanium silicide, cobalt silicide, nickel silicide, etc. For example, the metal silicide pattern 500 may be between the lower contact plug 475 and the protection pattern 510.

The upper contact plug 620 may include a second metal pattern 610 and a conductive spacer 535 covering a lower surface of the second metal pattern 610. The second metal pattern 610 may include a metal, e.g., tungsten, and the conductive spacer 535 may include a metal nitride, e.g., titanium nitride. For example, a horizontal portion of the conductive spacer 535 may be between the and the protection pattern 510 and the second metal pattern 610. The protection pattern 510 may include a material having a high etch selectivity with respect to the conductive spacer 535, e.g., a metal such as tungsten.

In example embodiments, a plurality of upper contact plugs 620 may be spaced apart from each other in the first and second directions D1 and D2, and may be arranged in a honeycomb pattern or a lattice pattern in a plan view. Each of the upper contact plugs 620 may have a shape of, e.g., a circle, an ellipse, or a polygon in a plan view. The sixth insulation pattern 590 may be formed between the upper contact plugs 620 neighboring each other. The sixth insulation pattern 590 may include an insulating nitride, e.g., silicon nitride.

Hereinafter, the bit line structure 395 and the spacer structures 460 disposed on the opposite sidewalls thereof may be referred to as an extension structure. The extension structure may include a first sidewall and a second sidewall facing the first sidewall, e.g., the first sidewall and the second sidewall may be opposite sidewalls of the extension structure. The first sidewall of a first one of the extension structures may face the second sidewall of a second one of the extension structures adjacent thereto in the first direction D1.

The conductive spacer 535 may be disposed on the first sidewall of the extension structure, but may not be disposed on the second sidewall of the extension structure. Accordingly, the conductive spacer 535 may contact (e.g., directly contact) the first sidewall of the first one of the extension structure, but may not contact the second sidewall of the second one of the extension structure adjacent thereto in the first direction D1. For example, as illustrated in FIG. 2, the conductive spacer 535 may be only on one side of the bit line structure 395, e.g., the conductive spacer 535 may be only on one of the spacer structures 460 that are on opposite sidewalls of the bit line structure 395.

The conductive spacer 535 may contact an upper portion of the first sidewall of the extension structure and upper surfaces of the first capping pattern 385 and the protection pattern 510 adjacent thereto. Accordingly, the conductive spacer 535 may have a shape of a staircase, e.g., the conductive spacer 535 may have horizontal portion on the protection pattern 510 and a vertical portion extending along the spacer structure 460 and a portion of the first capping pattern 385. The sixth insulation pattern 590 may extend through the upper contact plug 620 to contact an upper portion of the second sidewall of the extension structure and upper surfaces of the first capping pattern 385 and the protection pattern 510 adjacent thereto. For example, as illustrated in FIG. 2, the sixth insulation pattern 590 and the conductive spacer 535 may be on opposite sidewalls of the extension structure, e.g., on opposite sidewalls of each of the bit line structures 395.

In example embodiments, a width of the metal pattern 610 in the horizontal direction (e.g., in the first direction D1) may decrease as the distance in the vertical direction from the upper surface of the substrate 100 increases. For example, as illustrated in FIG. 2, a width of a portion of the metal pattern 610 above the bit line structure 395 may be larger than a width of a portion of the metal pattern 610 horizontally overlapping the bit line structure 395.

The second etch stop pattern 700 may be formed on the sixth insulation pattern 590, the upper contact plug 620, and the second capping pattern 485. The second etch stop pattern 700 may include an insulating nitride, e.g., silicon boronitride, silicon nitride, etc.

The capacitor 740 may include a lower electrode 710, a dielectric layer 720, and an upper electrode 730 that are sequentially stacked, and the lower electrode 710 may extend through the second etch stop pattern 700 to contact an upper surface of the upper contact plug 620. Each of the lower electrode 710 and the upper electrode 730 may include, e.g., a metal, a metal nitride, a metal silicide, and the dielectric layer 720 may include, e.g., a metal oxide.

As described below, the bit line structure 395 included in the semiconductor device may have a low aspect ratio, and accordingly, the difficulty of manufacturing the semiconductor device may be alleviated. Also, an electrical short between the bit line structures 395 adjacent to each other may be reduced, and thus the semiconductor device may have improved electrical characteristics.

FIGS. 3 to 23 are plan views and cross-sectional views of stages in a method of manufacturing a semiconductor device according to example embodiments.

Specifically, FIGS. 3, 5, 8, 12, 17 and 22 are the plan views, FIG. 4 includes cross-sectional views taken along lines A-A′ and B-B′, respectively, of FIG. 1, and FIGS. 6-7, 9-11, 13-16, 18-21 and 23 are cross-sectional views taken along line A-A′ of FIG. 1 of corresponding plan views.

Referring to FIGS. 3 and 4, an upper portion of the substrate 100 may be removed to form a first recess, and the isolation pattern 110 may be formed in the first recess. As the isolation pattern 110 is formed on the substrate 100, the active pattern 105 of which a sidewall is covered by the isolation pattern 110 may be defined.

The active pattern 105 and the isolation pattern 110 on the substrate 100 may be partially etched to form a second recess extending in the first direction D1, and the gate structure 160 may be formed in the second recess. In example embodiments, the gate structure 160 may extend in the first direction D1, and a plurality of gate structures may be spaced apart from each other in the second direction D2.

Referring to FIGS. 5 and 6, the insulating layer structure 230 may be formed on the active pattern 105, the isolation pattern 110, and the gate structure 160. The insulating layer structure 230 may include the first to third insulating layers 200, 210, and 220 sequentially stacked.

The insulating layer structure 230 may be patterned, and the active pattern 105, the isolation pattern 110, and the gate mask 150 included in the gate structure 160 may be partially etched using the patterned insulating layer structure 230 as an etching mask to form the first opening 240. In example embodiments, the insulating layer structure 230 may have a circular shape or an elliptical shape in a plain view, and a plurality of insulating layer structures 230 may be spaced apart from each other in the first and second directions D1 and D2. Each of the insulating layer structures 230 may overlap end portions of ones of the active patterns 105 neighboring in the third direction D3, which may face each other, in the vertical direction.

Referring to FIG. 7, a first conductive layer 250, a first barrier layer 260, a second conductive layer 270, and a first mask layer 280, which may collectively form a conductive structure layer, may be sequentially stacked on the insulating layer structure 230, and the active pattern 105, the isolation pattern 110 and the gate structure 160 exposed by the first opening 240. The first conductive layer 250 may fill the first opening 240.

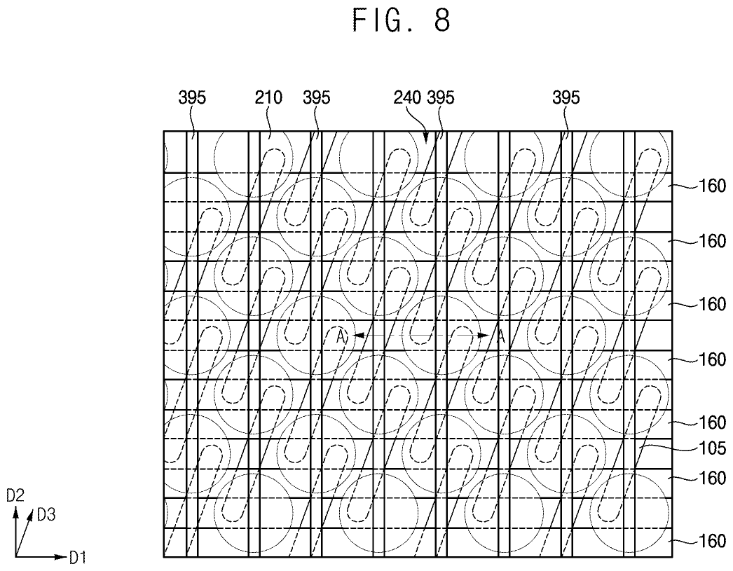

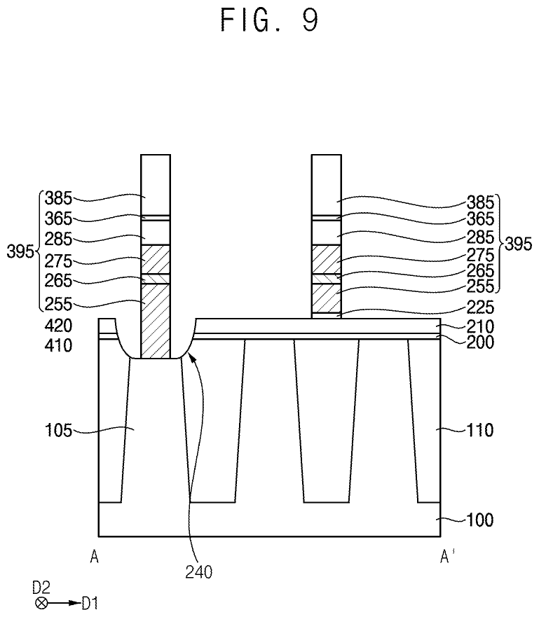

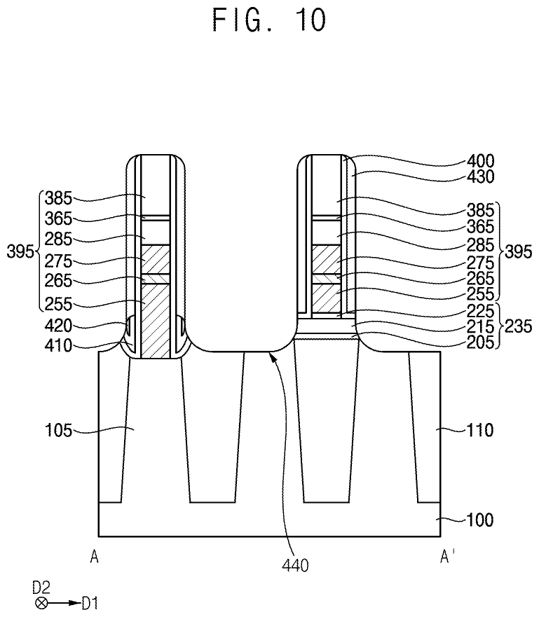

Referring to FIGS. 8 and 9, a first etch stop layer and a first capping layer may be sequentially formed on the conductive structure layer, the first capping layer may be etched to form the first capping pattern 385, and the first etch stop layer, the first mask layer 280, the second conductive layer 270, the first barrier layer 260 and the first conductive layer 250 may be sequentially etched using the first capping pattern 385 as an etch mask. In example embodiments, the first capping pattern 385 may extend in the second direction D2, and a plurality of first capping patterns 385 may be spaced apart from each other in the first direction D1.

By the etching process, the first conductive pattern 255, the first barrier pattern 265, the second conductive pattern 275, the first mask 285, the first etch stop pattern 365, and the first capping pattern 385 may be formed on the first opening 240, and the third insulation pattern 225, the first conductive pattern 255, the first barrier pattern 265, the second conductive pattern 275, the first mask 285, the first etch stop pattern 365, and the first capping pattern 385 may be sequentially stacked on the second insulating layer 210 of the insulating layer structure 230 at an outside of the first opening 240.

Hereinafter, the first conductive pattern 255, the first barrier pattern 265, the second conductive pattern 275, the first mask 285, the first etch stop pattern 365 and the first capping pattern 385 sequentially stacked may be referred to as the bit line structure 395. The first conductive pattern 255, the first barrier pattern 265, and the second conductive pattern 275 may form the conductive structure of the bit line structure 395, and the first mask 285, the first etch stop pattern 365, and the first capping pattern 385 may form the insulation structure of the bit line structure 395. In example embodiments, the bit line structure 395 may extend in the second direction D2, and a plurality of bit line structures 395 may be spaced apart from each other in the first direction D1.

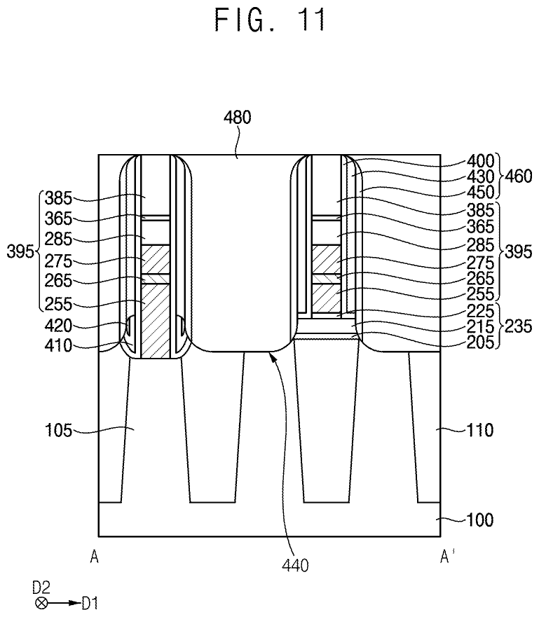

Referring to FIG. 10, a first spacer layer may be formed on the substrate 100 on which the bit line structure 395 is formed, and fourth and fifth insulating layers may be sequentially formed on the first spacer layer. The first spacer layer may also cover a sidewall of the third insulation pattern 225 under the bit line structure 395 on the second insulating layer 210, and the fifth insulating layer may fill a remaining portion of the first opening 240.

The fourth and fifth insulating layers may be etched by an etching process. In example embodiments, the etching process may be a wet etching process using, e.g., phosphoric acid (H₂PO₃), SC1, and hydrofluoric acid (HF) as an etchant, and portions of the fourth and fifth insulating layers except for portions thereof in the first opening 240 may be removed. Accordingly, most portion of a surface of the first spacer layer, i.e., all portions of the surface of the first spacer layer except for a portion of the surface thereof in the first opening 240 may be exposed, and the fourth and fifth insulating layers remaining in the first opening 240 may form the fourth and fifth insulation patterns 410 and 420, respectively.

A second spacer layer may be formed on the exposed surface of the first spacer layer and the fourth and fifth insulation patterns 410 and 420 in the first opening 240. The second spacer layer may be anisotropically etched to form the second spacer 430 covering a sidewall of the bit line structure 395 on the surface of the first spacer layer and on the fourth and fifth insulation patterns 410 and 420.

A dry etching process may be performed using the first capping pattern 385 and the second spacer 430 as an etch mask to form a second opening 440 exposing an upper surface of the active pattern 105, and upper surfaces of the isolation pattern 110. The gate mask 150 may also be exposed by the second opening 440.

By the dry etching process, portions of the first spacer layer on upper surfaces of the first capping pattern 385 and the second insulating layer 210 may be removed, and thus the first spacer 400 may be formed on the sidewall of the bit line structure 395. By the dry etching process, the first and second insulating layers 200 and 210 may be partially removed to remain as the first and second insulation patterns 205 and 215, respectively, under the bit line structure 395. The first to third insulation patterns 205, 215, and 225 sequentially stacked under the bit line structure 395 may form a first insulation pattern structure.

Referring to FIG. 11, a third spacer layer may be formed on an upper surface of the first capping pattern 385, an outer sidewall of the second spacer 430, portions of the upper surfaces of the fourth and fifth insulation patterns 410 and 420, and the upper surfaces of the active pattern 105, the isolation pattern 110 and the gate mask 150 exposed by the second opening 440. The third spacer layer may be anisotropically etched to form the third spacer 450 covering the sidewall of the bit line structure 395. The first to third spacers 400, 430 and 450 sequentially stacked on the sidewall of the bit line structure 395 in the horizontal direction may be referred to as the spacer structure 460.

A first sacrificial layer may be formed to fill the second opening 440 on the substrate 100 to a sufficient height, and an upper portion of the first sacrificial layer may be planarized until the upper surface of the first capping pattern 385 is exposed to form a first sacrificial pattern 480 in the second opening 440. For example, the first sacrificial pattern 480 may extend (e.g., lengthwise) in the second direction D2, and a plurality of first sacrificial patterns 480 may be spaced apart from each other in the first direction D1 by the bit line structures 395. The first sacrificial pattern 480 may include, e.g., an oxide such as silicon oxide.

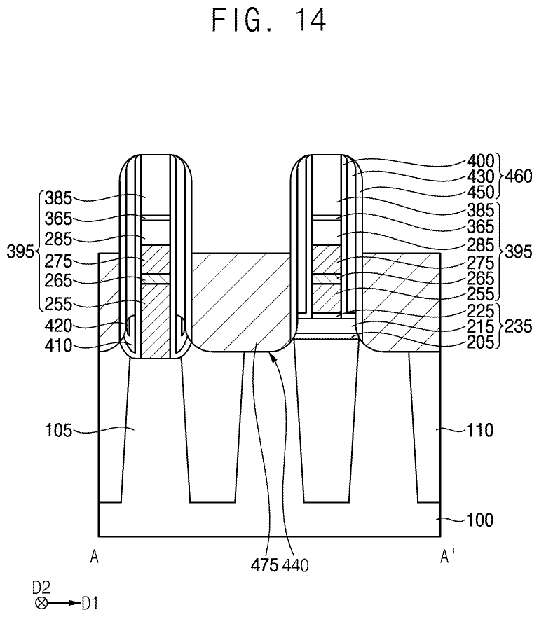

Referring to FIGS. 12 and 13, a second mask including a plurality of third openings, each of which may extend in the first direction D1 and spaced apart from each other in the second direction D2, may be formed on the first capping pattern 385, the first sacrificial pattern 480, and the spacer structure 460, and the first sacrificial pattern 480 may be etched using the second mask as an etching mask.

In example embodiments, each of the third openings may overlap a region between the gate structures 160 in the vertical direction. By the etching process, a fourth opening exposing the upper surfaces of the active pattern 105 and the isolation pattern 110 may be formed between the bit line structures 395 on the substrate 100.

The second mask may be removed, a lower contact plug layer may be formed to fill the fourth opening to a sufficient height, and an upper portion of the lower contact plug layer may be planarized until the upper surface of the first capping pattern 385 and upper surfaces of the first sacrificial pattern 480 and the spacer structure 460 are exposed.

Accordingly, the lower contact plug layer may be transformed into a plurality of lower contact plugs 475 spaced apart from each other in the second direction D2 between the bit line structures 395. Additionally, the first sacrificial pattern 480 extending in the second direction D2 between the bit line structures 395 may be divided into a plurality of parts in the second direction D2 by the lower contact plugs 475.

The first sacrificial pattern 480 may be removed to form a fifth opening, and the second capping pattern 485 may be formed to fill the fifth opening. In example embodiments, the second capping pattern 485 may overlap the gate structure 160 in the vertical direction.

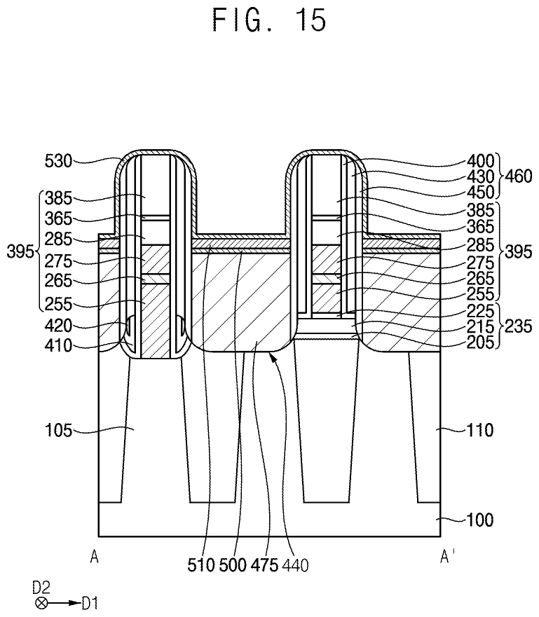

Referring to FIG. 14, an upper portion of the lower contact plug 475 may be removed by, e.g., an etch-back process. In example embodiments, by the etch-back process, an upper surface of the lower contact plug 475 may be formed at a height between heights of an upper surface and a lower surface of the second conductive pattern 275, e.g., relative to a bottom of the substrate 100.

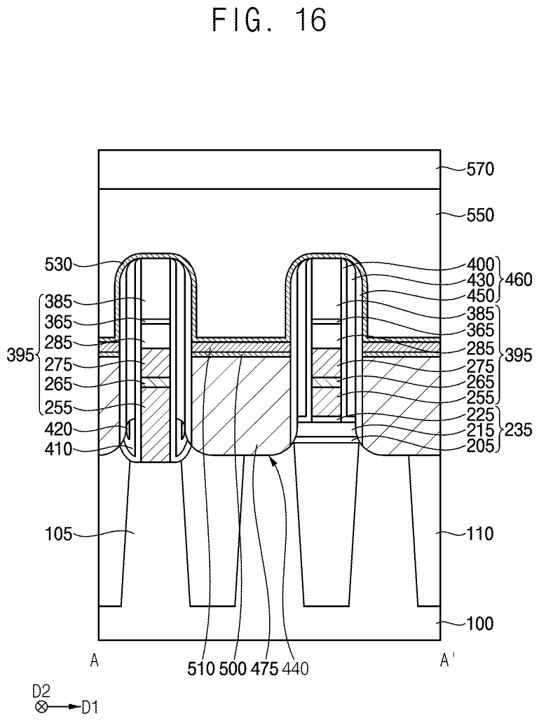

Referring to FIG. 15, a metal silicide pattern 500 may be formed on the exposed upper surface of the lower contact plug 475. In example embodiments, the metal silicide pattern 500 may be formed by forming a first metal layer on the first and second capping patterns 385 and 485, the fourth spacer 490 and the lower contact plug 475, performing a heat treatment thereon, and removing an unreacted portion of the first metal layer.

A protection pattern 510 may be formed on the first and second capping patterns 385 and 485, the spacer structure 460, the metal silicide pattern 500, and the lower contact plug 475. In example embodiments, the protection pattern 510 may include a material having a high selectivity with respect to a material included in the conductive spacer layer 530 to be formed subsequently, e.g., a metal such as tungsten. In example embodiments, the protection pattern 510 may be formed by forming a protection layer on the first and second capping patterns 385 and 485, the spacer structure 460, the metal silicide pattern 500 and the lower contact plug 475, and removing an upper portion of the protection layer by an etch-back process.

The conductive spacer layer 530 may be, e.g., continuously, formed on the first and second capping patterns 385 and 485, the spacer structure 460, and the protection pattern 510. The conductive spacer layer 530 may include a metal nitride, e.g., titanium nitride.

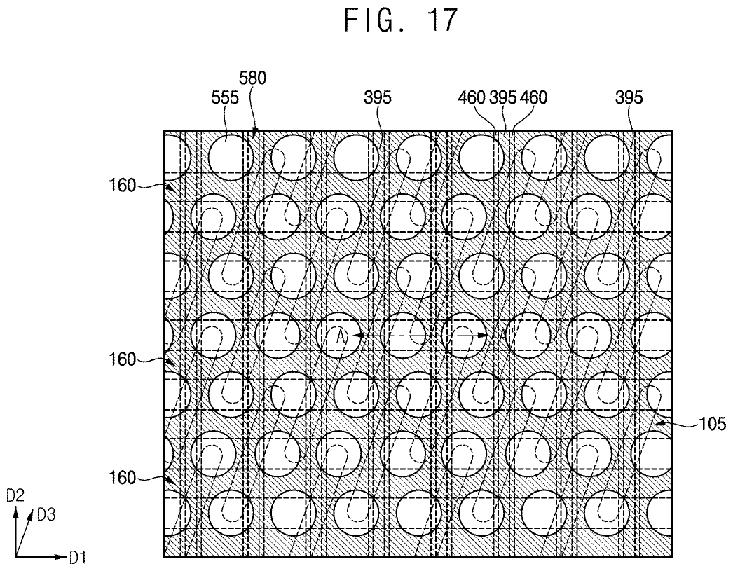

Referring to FIG. 16, a second sacrificial layer 550 may be formed on the conductive spacer layer 530 to fill a space between the bit line structures 395, and a third mask layer 570 may be formed on the second sacrificial layer 550. The second sacrificial layer 550 may include a material having a high etch selectivity with respect to the conductive spacer layer 530, e.g., an oxide such as silicon oxide.

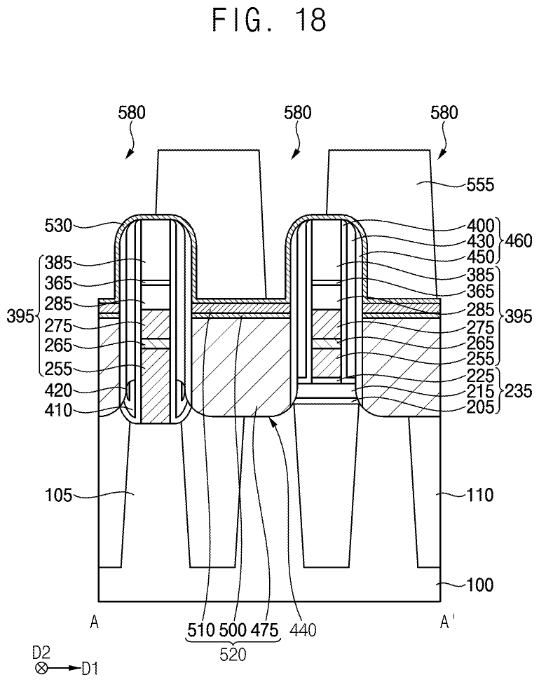

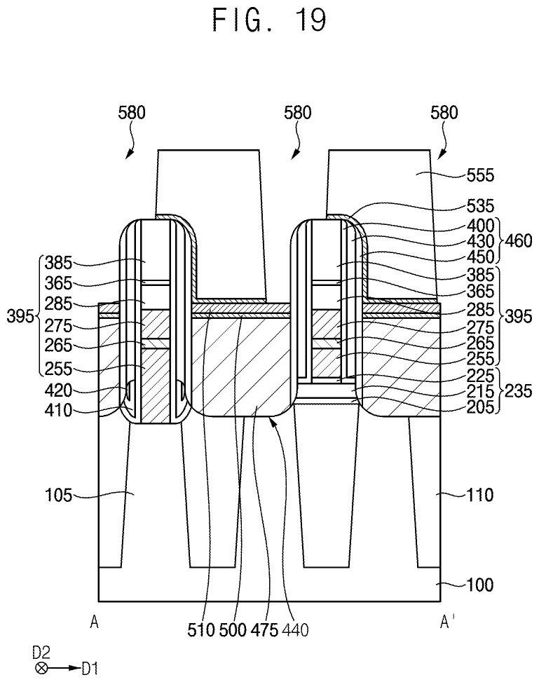

Referring to FIGS. 17 and 18, the third mask layer 570 may be patterned to form a third mask including a sixth opening, and the second sacrificial layer 550 may be etched by an etching process using the third mask as an etch mask to form a second sacrificial pattern 555.

By the etching process, a seventh opening 580 partially exposing an upper surface of the conductive spacer layer 530 may be formed, and the conductive spacer layer 530 including the material having a high etching selectivity with respect to the second sacrificial layer 550 may serve as an etch stop layer. In example embodiments, a plurality of second sacrificial patterns 555 may be spaced apart from each other in the first direction D1 by the seventh opening 580.

In example embodiments, the second sacrificial pattern 555 may have a shape of a circle, an ellipse, or a rounded polygon in a plan view, and the second sacrificial pattern 555 may be arranged, e.g., in a honeycomb pattern in the first and second directions D1 and D2.

The third mask may be removed during the etching process.

Referring to FIG. 19, a portion of the conductive spacer layer 530 exposed by the seventh opening 580 may be removed to partially expose the upper surface of the protection pattern 510. The conductive spacer layer 530 may be transformed into the conductive spacer 535.

The etching process may be performed by, e.g., a wet etching process using sulfuric acid (H₂SO₄) as an etchant. The protection pattern 510 may include the material having a high etching selectivity with respect to the material included in the conductive spacer layer 530, and thus the metal silicide pattern 500 covered by the protection pattern 510 may remain unetched during the etching process and be protected without being exposed to the etchant.

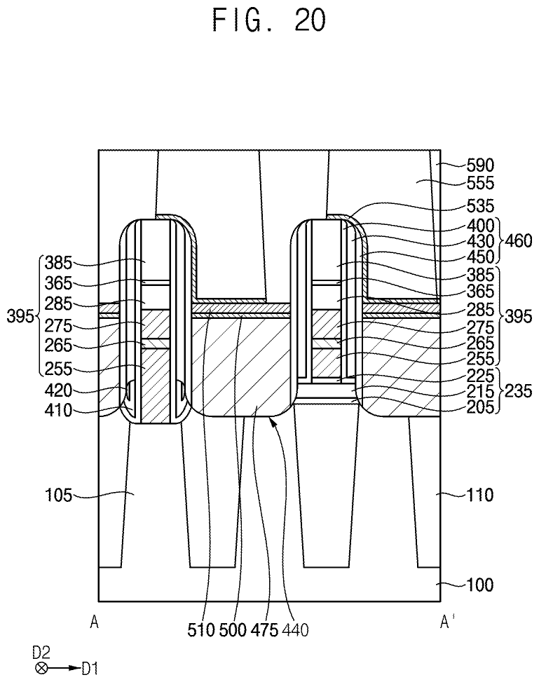

Referring to FIG. 20, a sixth insulating layer may be formed on the exposed upper surface of the protection pattern 510, an outer sidewall and an upper surface of the spacer structure 460 and an upper surface of the first capping pattern 385 to fill the seventh opening 580, and a planarization process may be performed on the sixth insulating layer until an upper surface of the second sacrificial pattern 555 is exposed to form the sixth insulation pattern 590. The planarization process may include, e.g., a chemical mechanical polishing (CMP) process and/or an etch-back process.

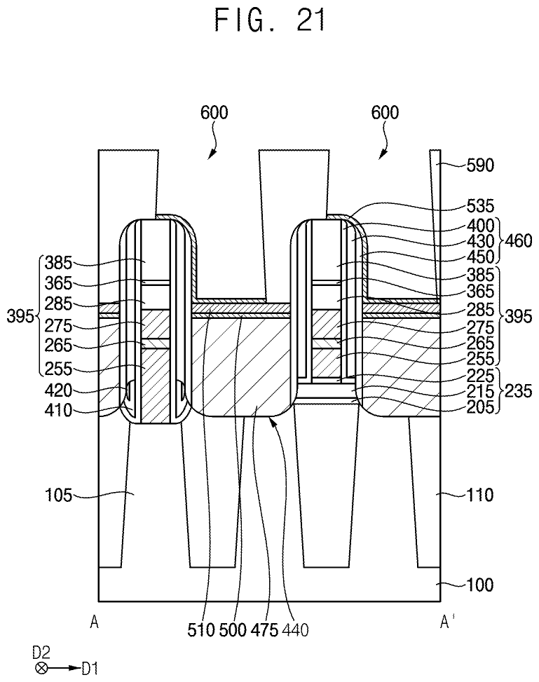

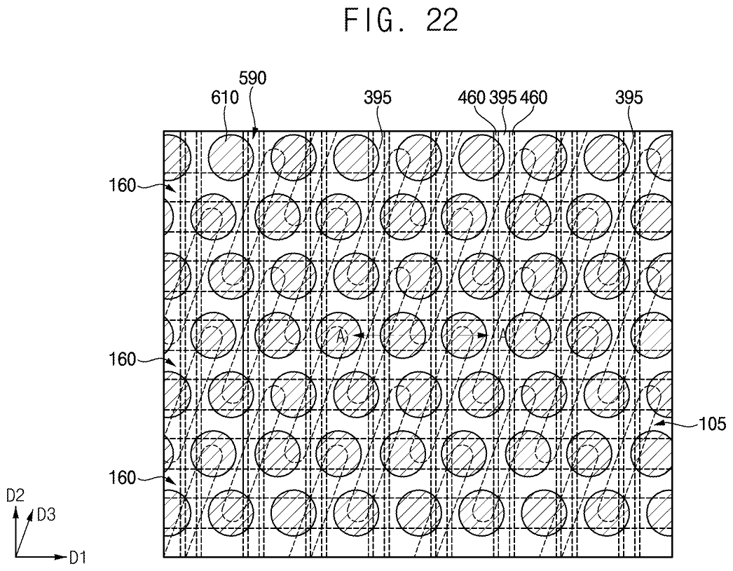

Referring to FIG. 21, an eighth opening 600 may be formed by removing the second sacrificial pattern 555, and the upper surface of the conductive spacer 535 may be exposed by the eighth opening 600. In example embodiments, the second sacrificial pattern 555 may be removed by a wet etching process and/or a dry etching process.

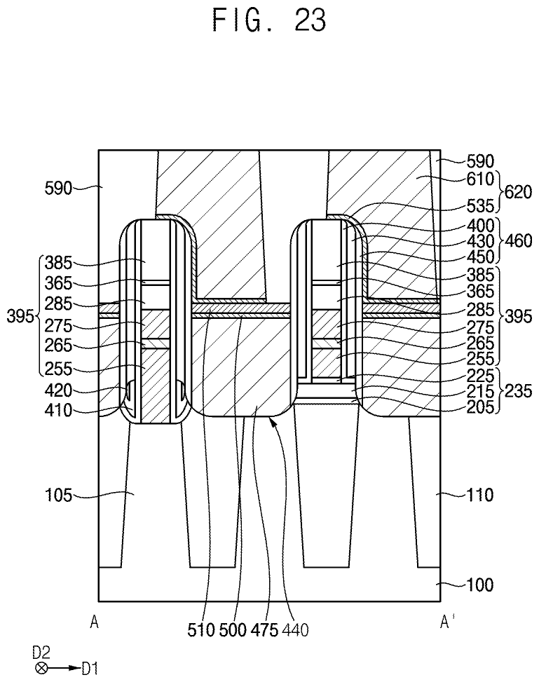

Referring to FIGS. 22 and 23, a metal pattern 610 may be formed in the eighth opening 600. In example embodiments, a second metal layer may be formed on the exposed conductive spacer 535 to fill the eighth opening 600, and a planarization process may be performed on the second metal layer until an upper surface of the sixth insulation pattern 590 is exposed to form a metal pattern 610. The planarization process may include, e.g., a CMP process and/or an etch-back process.

The metal pattern 610 and the conductive spacer 535 covering a lower surface of the metal pattern 610 may form the upper contact plug 620. The lower contact plug 475, the metal silicide pattern 500, the protection pattern 510, and the upper contact plug 620 collectively form the contact plug structure.

Referring to FIGS. 1 and 2 again, the second etch stop pattern 700 and a mold layer may be sequentially formed on the sixth insulation pattern 590 and the upper contact plug 620, a ninth opening may be formed to expose an upper surface of the upper contact plug 620, and the lower electrode 710 may be formed in the ninth opening. The mold layer may be removed, and the dielectric layer 720 and the upper electrode 730 may be sequentially formed on the lower electrode 710 and the second etch stop pattern 700. Accordingly, the capacitor 740 including the lower electrode 710, the dielectric layer, and the upper electrode 730 may be formed, and the manufacturing of the semiconductor device may be completed.

As described above, in the method of manufacturing the semiconductor device according to example embodiments, the conductive spacer layer 530 may be, e.g., conformally and continuously, formed on the lower contact plug 475, the first and second capping patterns 385 and 485, and the spacer structure 460, and the second sacrificial layer 550 may be formed to fill the space between the bit line structures 395, and the etching process may be performed on the second sacrificial layer 550 using the conductive spacer layer 530 as an etch stop layer to form the seventh opening 580 exposing the portion of the conductive spacer layer 530.

The conductive spacer 535 may be formed by removing the portion of the conductive spacer layer 530 exposed by the seventh opening 580, the sixth insulation pattern 590 may be formed in the seventh opening 580, and the metal pattern 610 may be formed in the eighth opening 600 that may be formed by removing the second sacrificial pattern 555 remaining after the etching process. Accordingly, the upper contact plug 620 including the conductive spacer 535 and the metal pattern 610 may be formed.

If an upper contact plug were to be formed by forming a metal layer on the lower contact plug 675 and patterning the metal layer, i.e., if an upper contact plug were to be formed by a positive patterning process (e.g., directly patterning the metal layer), the insulation structure included in the bit line structure 395 would have been etched together with the metal layer during the patterning process. In this case, the insulation structure could have been over-etched, and thus, the conductive structure included in the bit line structure under the insulation structure could have been also partially etched. As a result, the electrical characteristics of the bit line structure could have been deteriorated, and would have required forming the insulation structure to have a sufficient thickness, or forming an additional spacer, in order to protect the conductive structure from partial etching during patterning of the metal layer.

However, formation of the insulation structure with a sufficient thickness, or forming an additional spacer, would have increased the aspect ratio of the bit line structure 395 including the insulation structure, thereby increasing the formation difficulty of the bit line structure 395, as well as the process time and cost of the formation of the bit line structure 395. In addition, an electrical short could have occurred between the upper contact plugs adjacent to each other due to the metal layers remaining after the patterning process of the metal layer.

In contrast, in the method of manufacturing the semiconductor device according to example embodiments, instead of forming the upper contact plug 620 by patterning a metal layer, the sixth insulation pattern 590 may be formed in the seventh opening 580 that is formed by partially removing the second sacrificial layer 550, the metal pattern 610 may be formed in the eighth opening 600 that is formed by removing the remaining second sacrificial pattern 555, and the conductive spacer layer 530 may serve as an etch stop layer during the formation of the seventh opening 580. Thus, while forming the upper contact plug 620, the upper portion of the bit line structure 395, i.e., the insulation structure, may not be removed.

Accordingly, the insulation structure does not need to be thick, and thus, the aspect ratio of the bit line structure 395 including the insulation structure may be lowered. Hence, the difficulty of forming the bit line structure 396 and/or other elements may be lowered. In addition, there is no need to form an additional spacer, and thus, the complexity of the entire process may be reduced.

Furthermore, instead of a positive patterning process, the second metal layer may be formed to fill the eighth opening 600 which is formed by removing the second sacrificial pattern 555, and the planarization process may be performed thereon to form the upper contact plug 620. Thus, an electrical short (e.g., potentially caused due to the conductive material remaining between adjacent upper contact plugs 620) may not occur.

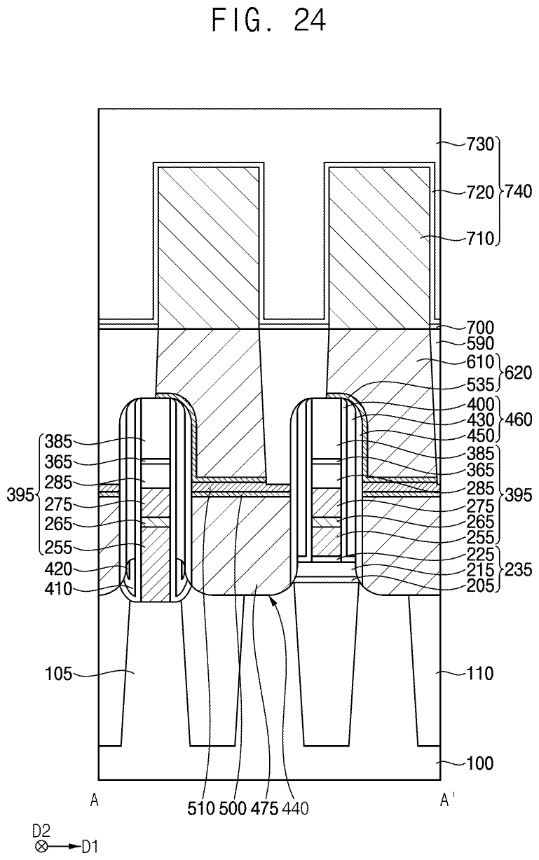

FIG. 24 is a cross-sectional view illustrating a semiconductor device in accordance with example embodiments, which corresponds to FIG. 2. This semiconductor device may be substantially the same as or similar to that of FIGS. 1 to 2, except for the shapes of the protection pattern 510 and the sixth insulation pattern 590, and thus repeated explanations are omitted herein.

Referring to FIG. 24, by the processes illustrated with reference to FIG. 19, the conductive spacer layer 530 exposed by the seventh opening 580 may be removed by a wet etching process. However, a portion of the protection pattern 510 may be etched together with the conductive spacer layer 530 by the wet etching process. Accordingly, an uppermost surface of the protection pattern 510 may be formed to be higher than a lowermost surface of the sixth insulation pattern 590, e.g., relative to a bottom of the substrate 100.

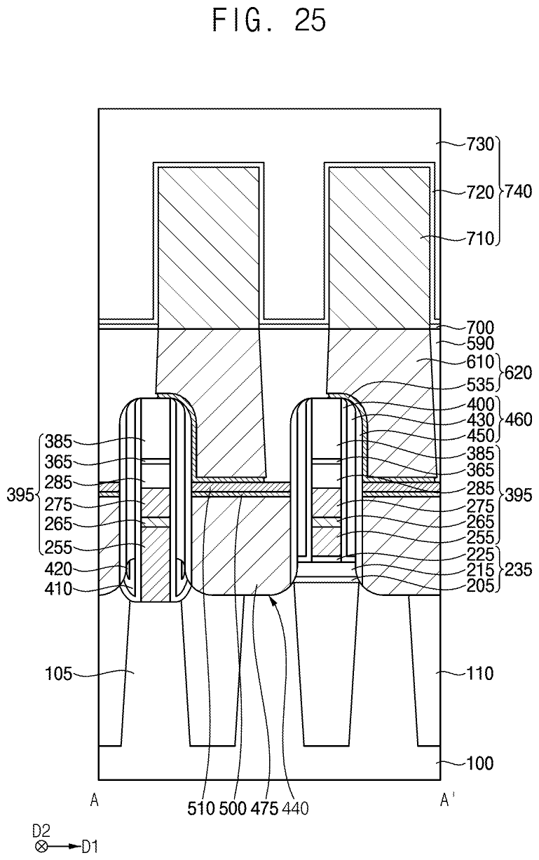

FIG. 25 is a cross-sectional view illustrating a semiconductor device in accordance with example embodiments, which corresponds to FIG. 2. This semiconductor device may be substantially the same as or similar to that of FIGS. 1 to 2, except for the shape of the conductive spacer 535, and thus repeated explanations are omitted herein.

Referring to FIG. 25, by the processes illustrated with reference to FIG. 19, the conductive spacer layer 530 exposed by the seventh opening 580 may be removed by a wet etching process. However, a portion of the conductive spacer layer 530 formed under the second sacrificial pattern 555 may be etched together with the exposed portion of the conductive spacer layer 530. Accordingly, a third recess may be formed on a sidewall in the first direction D1 of a portion of the conductive spacer 535 on the protection pattern 510, and the sidewall in the first direction D1 of the conductive spacer 535 may have a concave shape and not be aligned in the vertical direction with a sidewall of a portion of the metal pattern 610 corresponding thereto.

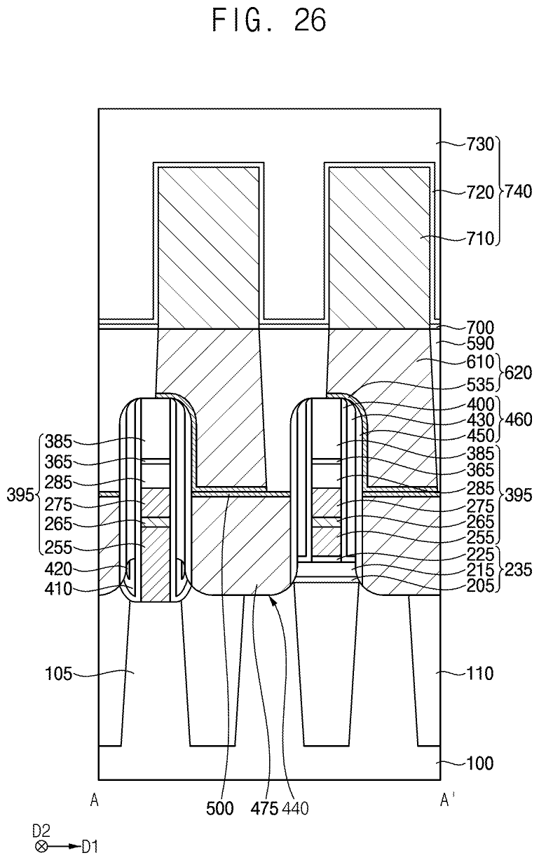

FIG. 26 is a cross-sectional view illustrating a semiconductor device in accordance with example embodiments, which corresponds to FIG. 2. This semiconductor device may be substantially the same as or similar to that of FIGS. 1 to 2, except for not including the protection pattern 510, and thus repeated explanations are omitted herein.

Referring to FIG. 26, the semiconductor device may not include the protection pattern 510, and thus the conductive spacer 535 may be formed on and contact the metal silicide pattern 500.

By way of summation and review, an aspect ratio of the bit line structure may increase due to an increased thickness of the insulation structure in the bit line structure, thereby increasing the complexity of the process of forming the DRAM device. In addition, during the patterning of the metal layer of the upper plug contact, the metal layer may not be completely removed and some of the metal layer may remain, thereby causing potential electrical shorts between the upper contact plugs of the DRAM.

In contrast, example embodiments provide a semiconductor device having improved characteristics. That is, in the method of manufacturing the semiconductor device according to example embodiments, the upper contact plug, on which the capacitor is disposed, may be formed using a negative patterning method (e.g., metal deposition into a pre-made opening without etching the metal) instead of a positive patterning method (e.g., direct patterning of a metal layer), thereby reducing a required height of the insulation structure in the bit line structure. Thus, the aspect ratio of the bit line structure including the insulation structure may be reduced, and the difficulty of forming the bit line structure and other elements may be reduced. In addition, as the negative patterning method is used, an electrical short between the upper contact plugs may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
an active pattern on a substrate;
a gate structure extending through an upper portion of the active pattern in a first direction substantially parallel to an upper surface of the substrate;
a bit line structure on a central portion of the active pattern, the bit line structure extending in a second direction substantially parallel to the upper surface of the substrate and substantially perpendicular to the first direction;
a first spacer structure and a second spacer structure on a first sidewall and a second sidewall of the bit line structure, respectively, the first sidewall and the second sidewall being opposite sidewalls of the bit line structure in the first direction;
a lower contact plug on each of opposite end portions of the active pattern; and
an upper contact plug on the lower contact plug, the upper contact plug including:
a conductive pattern, and
a conductive spacer covering a lower surface of the conductive pattern, the conductive spacer contacting an outer sidewall only of the first spacer structure among the first spacer structure and the second spacer structure.

2. The semiconductor device as claimed in claim 1, wherein the conductive spacer includes a metal nitride.

3. The semiconductor device as claimed in claim 1, wherein the first spacer structure and the second spacer structure are symmetrical with respect to the bit line structure.

4. The semiconductor device as claimed in claim 1, wherein a sidewall in the first direction of a portion of the conductive spacer on the lower contact plug has a concave shape.

5. The semiconductor device as claimed in claim 1, further comprising a protection pattern between the lower contact plug and the upper contact plug.

6. The semiconductor device as claimed in claim 5, wherein the protection pattern includes a material having a high etch selectively with respect to a material included in the conductive spacer.

7. The semiconductor device as claimed in claim 6, wherein the conductive spacer includes a metal nitride, and the protection pattern includes a metal.

8. The semiconductor device as claimed in claim 5, further comprising an insulation pattern on the protection pattern, the insulation pattern contacting a sidewall of the upper contact plug, and a lowermost surface of the insulation pattern being lower than an uppermost surface of the protection pattern.

9. The semiconductor device as claimed in claim 8, further comprising a metal silicide layer between the lower contact plug and the upper contact plug, the insulation pattern contacting an upper surface of the metal silicide layer.

10. A semiconductor device, comprising:
an active pattern on a substrate;
a gate structure extending through an upper portion of the active pattern in a first direction substantially parallel to an upper surface of the substrate;
a bit line structure on a central portion of the active pattern, the bit line structure extending in a second direction substantially parallel to the upper surface of the substrate and substantially perpendicular to the first direction;
a spacer structure on each of opposite sidewalls of the bit line structure in the first direction;
a lower contact plug on each of opposite end portions of the active pattern; and
an upper contact plug on the lower contact plug, the upper contact plug including:
a conductive pattern, and
a conductive spacer covering a lower surface of the conductive pattern, the conductive spacer being on the spacer structure and the lower contact plug, and a cross-section in the first direction of the conductive spacer having a shape of a staircase.

11. The semiconductor device as claimed in claim 10, wherein the conductive spacer includes a metal nitride.

12. The semiconductor device as claimed in claim 10, wherein the spacer structure includes a first spacer structure and a second spacer structure on the opposite sidewalls of the bit line structure, respectively, the conductive spacer contacting an outer sidewall and an upper surface of the first spacer structure.

13. The semiconductor device as claimed in claim 12, wherein the first spacer structure and the second spacer structure are symmetrical with respect to the bit line structure.

14. The semiconductor device as claimed in claim 10, wherein a sidewall in the first direction of a portion of the conductive spacer on the lower contact plug has a concave shape.

15. The semiconductor device as claimed in claim 10, further comprising a protection pattern between the lower contact plug and the upper contact plug.

16. The semiconductor device as claimed in claim 15, further comprising an insulation pattern covering a sidewall of the upper contact plug, a lowermost surface of the insulation pattern being lower than an uppermost surface of the protection pattern.

17. A semiconductor device, comprising:
active patterns on a substrate;
an isolation pattern on the substrate, the isolation pattern covering sidewalls of the active patterns;
gate structures extending through upper portions of the active patterns and the isolation pattern in a first direction substantially parallel to an upper surface of the substrate, the gate structures being spaced apart from each other in a second direction substantially parallel to the upper surface of the substrate and substantially perpendicular to the first direction;
bit line structures extending in the second direction on central portions of the active patterns, the bit line structures being spaced apart from each other in the first direction;
a first spacer structure and a second spacer structure on a first sidewall and a second sidewall of each of the bit line structures, respectively, the first sidewall and the second sidewall being opposite each other in the first direction;
lower contact plugs on opposite end portions, respectively, of the active patterns;
metal silicide patterns on the lower contact plugs, respectively;
protection patterns on the metal silicide patterns, respectively, each of the protection patterns including a metal;
upper contact plugs on the protection patterns, respectively, each of the upper contact plugs including:
a conductive pattern, and
a conductive spacer covering a lower surface of the conductive pattern;
an insulation pattern on the protection patterns, the insulation pattern covering sidewalls of the upper contact plugs and contacting upper surfaces of the protection patterns; and
capacitors on the upper contact plugs, respectively.

18. The semiconductor device as claimed in claim 17, wherein the conductive spacer is in contact with an outer sidewall of only the first spacer structure among the first spacer structure and the second spacer structure.

19. The semiconductor device as claimed in claim 17, wherein the first spacer structure and the second spacer structure are symmetrical with respect to the bit line structure.

20. The semiconductor device as claimed in claim 17, wherein the protection patterns include a metal.
